(19) United States
(12) Patent Application Publication
(10) Pub. No.: US 2006/0237786 A1
(43) Pub. Date: Oct. 26, 2006

(54) Power semiconductor device

(75) Inventors: Hideaki Ninomiya, Kawasaki-shi (JP); Masanobu Tsuchitani, Kawasaki-shi (JP); Satoshi Teramae, Kawasaki-shi (JP); Masakazu Yamaguchi, Kawasaki-shi (JP); Koichi Sugiyama, Yokohama-shi (JP); Satoshi Urano, Yokohama-shi (JP); Keiko Kawamura, Yokohama-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Minato-ku (JP)

(21) Appl. No.: 11/384,260

(22) Filed: Mar. 21, 2006

(30) Foreign Application Priority Data
Apr. 22, 2005 (JP) 2005-124743

(51) Int. Cl. H01L 29/76

(52) U.S. Cl. 257/341

(57) ABSTRACT

A power semiconductor device according to the present invention comprises: a first conductive type base layer; a second conductive type base layer selectively formed on the first conductive type base layer; an insulation layer formed in the region on the first conductive type base layer on which the second conductive type base layer is not formed; a gate insulation film formed on the inner surface of a trench formed between the second conductive type base layer and the insulation layer so as to separate them from each other and to reach the first conductive type base layer from the surface of the second conductive type base layer; a first conductive type source layer selectively formed on the surface of the second conductive type base layer in contact with the gate insulation film; a gate electrode formed in the trench and insulated from the first conductive type base layer, the second conductive type base layer, and the first conductive type source layer by the gate insulation film; a main electrode electrically connected to the first conductive type base layer and the second conductive type base layer; and a first conductive type or second conductive type floating layer formed on the bottom of the insulation layer.

### CROSS-REFERENCE TO RELATED APPLICATIONS

This application is based upon and claims the benefit of priority from the prior Japanese Patent Application No. 2005-124743, filed on Apr. 22, 2005, the entire contents of which are incorporated herein by reference.

### BACKGROUND OF THE INVENTION

1. Field of the Invention

The present invention relates to a MOS type power semiconductor device of, for example, a vertical IGBT, a lateral IGBT, and the like.

2. Background Art

Recently, a vertical IGBT (Insulated Gate Bipolar Transistor) having a trench gate structure is widely used as a power semiconductor device having breakdown voltage of at least 600 V. A vertical IGBT having a conventional trench structure has an n-type base layer, a p-type base layer selectively formed on the n-type base layer, a p-type floating layer formed in a dummy region on the n-type base layer separated from the p-type base layer through a trench, a gate electrode formed in the trench through a gate insulation film, an n-type source layer selectively formed on the surface of the p-type base layer in contact with the gate insulation film, a p-type contact layer selectively formed on the surface of the p-type base layer, and an emitter electrode electrically connected to the n-type source layer and the p-type base layer.

The vertical IGBT having the trench structure operates as described below. First, when a bias, which is positive potential with respect to the emitter electrode, is applied to the gate electrode, an inversion layer is formed on the surface of the insulation film of the p-type base layer, and electrons are injected into the n-type base layer. Accordingly, holes are injected into the n-type base layer from a collector side, thereby the IGBT is placed in a turned-on state. Then, the injected holes travel in the n-type base layer and flow into the p-type base layer. It is reported that when a region such as the p-type floating layer in which the holes do not flow is formed at the time, the holes are accumulated on the emitter electrode side of the n-type base layer, thereby injection of electrons is accelerated. A larger resistance component to the holes in the n-type base layer just under p-type base layer sandwiched by the trench more enhances the electron injection promotion effect (“A 4500 V Injection Enhanced Insulated Gate Bipolar Transistor (IEGT) Operating in a Mode Similar to a Thyristor”, M. Kitagawa et al., IEEE IEDM Technical Digest (1993), pp. 679-682).

However, in the trench MOS gate type IGBT described above, a gate-collector capacitance Cgc generated between the p-type floating layer and the gate electrode more increases than that of an ordinary IGBT. Accordingly, the charge/discharge time of the gate-collector capacitance Cgc increases when the IGBT is switched on and off, from which a problem arises in that the switching speed of the trench MOS gate type IGBT is reduced and further the current capacitance of a gate drive circuit cannot be reduced.

### SUMMARY OF THE INVENTION

A power semiconductor device according to an aspect of the present invention comprises: a first conductive type base layer; a second conductive type base layer selectively formed on the first conductive type base layer; an insulation layer formed in the region on the first conductive type base layer on which the second conductive type base layer is not formed; a gate insulation film formed on the inner surface of a trench formed between the second conductive type base layer and the insulation layer so as to separate them from each other and to reach the first conductive type base layer from the surface of the second conductive type base layer; a first conductive type source layer selectively formed on the surface of the second conductive type base layer in contact with the gate insulation film; a gate electrode formed in the trench and insulated from the first conductive type base layer, the second conductive type base layer, and the first conductive type source layer by the gate insulation film; a main electrode electrically connected to the first conductive type base layer and the second conductive type base layer; and a first conductive type or second conductive type floating layer formed on the bottom of the insulation layer.

A power semiconductor device according to another aspect of the present invention comprising: a first conductive type base layer; a second conductive type base layer selectively formed on the first conductive type base layer; an insulation layer formed in the region on the first conductive type base layer on which the second conductive type base layer is not formed; a gate insulation film formed on the inner surface of a first trench formed between the second conductive type base layer and the insulation layer to separate them from each other and to reach the first conductive type base layer from the surface of the second conductive type base layer; a first conductive type source layer selectively formed on the surface of the second conductive type base layer in contact with the first gate insulation film; a gate electrode formed in the first trench and insulated from the first conductive type base layer, the second conductive type base layer, and the first conductive type source layer by the gate insulation film; a main electrode electrically connected to the first conductive type source layer and the second conductive type base layer; and an electrode formed in a second trench to maintain the potential of the insulation layer, wherein the second trench is formed in the insulation layer so as not to reach the first conductive type base layer from the surface of the insulation layer.

A power semiconductor device according to further aspect of the present invention comprising: a first conductive type base layer; a second conductive type base layer selectively formed on the first conductive type base layer; a second conductive type dummy layer selectively formed in the region on the first conductive type base layer on which the second conductive type base layer is not formed; a gate insulation film formed on the inner surface of a trench formed between the second conductive type base layer and the second conductive type dummy layer so as to separate them from each other and to reach the first conductive type base layer from the surface of the second conductive type base layer; a first conductive type source layer selectively formed on the surface of the second conductive type base layer in contact with the gate insulation film; a gate electrode formed in the trench and insulated from the first conductive type base layer, the second conductive type base layer, and the first conductive type source layer by the gate insulation film; and a main electrode electrically connected to the first conductive type source layer and the second conductive type base layer, wherein the thickness of the gate insulation film on the side wall portion of the trench on the second conductive type dummy layer side and on the bottom of the trench is larger than the thickness of the gate insulation film facing the channel portion of the second conductive type base layer.

### BRIEF DESCRIPTION OF THE DRAWINGS

FIG. 1A is a sectional view showing a trench MOS gate structure of a power semiconductor device according to an embodiment 1 as an embodiment of the present invention;

FIG. 1B is a sectional view showing a trench MOS gate structure of a power semiconductor device according to an embodiment 1 as an embodiment of the present invention;

FIG. 2 is a sectional view showing a trench MOS gate structure of a power semiconductor device according to an embodiment 2 as an embodiment of the present invention;

FIG. 3 is a sectional view showing a trench MOS gate structure of a power semiconductor device according to an embodiment 3 as an embodiment of the present invention;

FIG. 4 is a sectional view showing a trench MOS gate structure of a power semiconductor device according to an embodiment 4 as an embodiment of the present invention;

FIG. 5 is a plan view showing a main portion of a trench MOS gate structure of a power semiconductor device according to an embodiment 5 as the embodiment of the present invention;

FIG. 6 is a sectional view showing a cross section of the power semiconductor device taken along the line A-A of FIG. 5;

FIG. 7 is a sectional view showing a cross section of the power semiconductor device taken along the line B-B of FIG. 5;

FIG. 8 is a plan view explaining an arrangement of a main portion of a power semiconductor device according to an embodiment 6 as the embodiment of the present invention;

FIG. 9 is a sectional view showing a cross section of the power semiconductor device taken along the line C-C of FIG. 8;

FIG. 10 is a sectional view showing a trench MOS gate structure of a power semiconductor device according to an embodiment 7 as an embodiment of the present invention;

FIG. 11 is a sectional view showing a trench MOS gate structure of a power semiconductor device according to an embodiment 8 as an embodiment of the present invention;

FIG. 12 is a sectional view showing a trench MOS gate structure of a power semiconductor device according to an embodiment 9 as an embodiment of the present invention;

FIG. 13 is a sectional view showing a trench MOS gate structure of a power semiconductor device according to an embodiment 10 as an embodiment of the present invention;

FIG. 14 is a sectional view showing a trench MOS gate structure of a power semiconductor device according to an embodiment 11 as an embodiment of the present invention; and

FIG. 15 is a sectional view showing a trench MOS gate structure of a power semiconductor device according to an embodiment 12 as an embodiment of the present invention.

### DETAILED DESCRIPTION OF THE INVENTION

Embodiments of the present invention will be described in detail with reference to the drawings. Note that although a trench gate structure is used in the following embodiments, the present invention can be applied to any power semiconductor device as long as it has a trench MOS gate structure such as a vertical trench IGBT, a lateral IGBT, and the like. Furthermore, although a case that a first conductive type is an n-type and a second conductive type is a p-type is described in the following embodiments, the same operation/working effect can be also achieved even if polarity is inversed.

### EMBODIMENT 1

An embodiment 1 described here is different from the conventional art described above in that an insulation layer is formed in a region of the surface of a power semiconductor device to which no emitter electrode is connected as well as an n-type or p-type floating layer is formed on the bottom of the insulation layer.

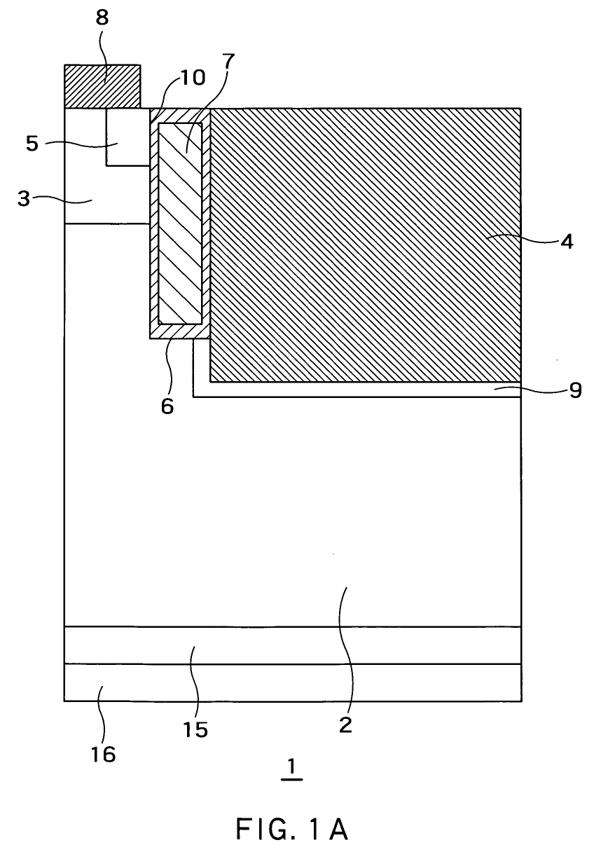

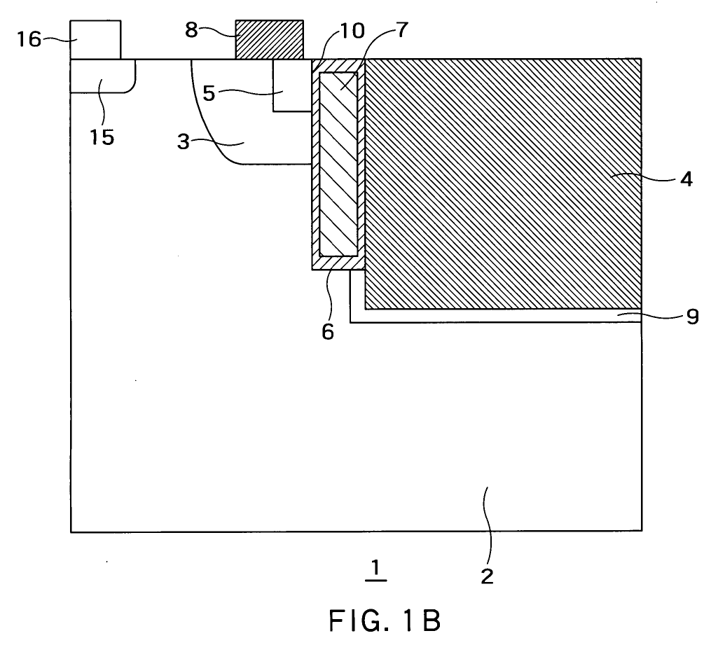

FIG. 1A, 1B are sectional view of a trench MOS gate structure of a power semiconductor device according to the embodiment 1 of the present invention.

In FIG. 1A, 1B, the power semiconductor device 1 includes an n-type (first conductive type) base layer 2, a p-type (second conductive type) base layer 3 selectively formed on the n-type base layer 2, and an insulation layer 4 selectively formed in a region (dummy region) in which the p-type base layer 3 on the n-type base layer 2 is not formed. The power semiconductor device 1 includes a trench 10 formed between the insulation layer 4 and the p-type base layer 3 so as to separate them from each other and to reach the n-type base layer 2 from the surface of the p-type base layer 3. The power semiconductor device 1 includes a gate insulation film 6 formed on the inner surface of the trench 10 and an n-type source layer 5 selectively formed on the surface of the p-type base layer 3 in contact with the gate insulation film 6. Furthermore, the power semiconductor device 1 includes a gate electrode 7 formed in the trench 10 and insulated from the n-type base layer 2, the p-type base layer 3, and the n-type source layer 5 by the gate insulation film 6, an emitter electrode 8 as a main electrode electrically connected to the n-type source layer 5 and the p-type base layer 3, and an n-type or p-type floating layer 9 formed on the bottom of the insulation layer 4 and having a concentration higher than the n-type base layer 2.

Since no capacitance is provided for the portion of the side surface of the gate insulation film 6 where the insulation layer 4 is formed, a collector-gate capacitance Cgc is reduced thereby. Furthermore, the insulation layer 4 is formed deeper than the trench 10, convergence of an electric field in the edge portion of the gate electrode 7 on the insulation layer 4 side is suppressed, thereby the collector-gate capacitance Cgc is further reduced.

Furthermore, since floating layer 9 is formed on the bottom of the insulation layer 4 so as to cover it, the breakdown voltage of the power semiconductor device 1 is improved. When it is mainly aimed to improve the breakdown voltage, the p-type is preferably selected for the floating layer 9, and when it is mainly aimed to improve an electron injection promotion effect, the n-type is preferably selected for the floating layer 9.

Note that an emitter electrode (not shown) and the like are formed on the gate insulation film 6 and the insulation layer 4. When, for example, a vertical trench IGBT is arranged, a collector electrode 16 is formed under the n-type base layer 2 through a p-type emitter layer 15 (shown in FIG. 1A). When, for example, a lateral trench IGBT is arranged, a collector electrode 16 is formed on a p-type emitter layer 15 selectively formed on the n-type base layer 2 (shown in FIG. 1B). Note that the vertical, lateral trench IGBT arrangements of the embodiment 1 are the same as those of the following embodiments. Furthermore, to permit the power semiconductor device 1 to carry out switching, the gate electrode 7 is formed in the trench 10 to face a channel portion of a MOS structure, that is, it is formed to have a depth from the n-type source layer 5 to the n-type base layer 2.

Doped silicon, for example, is used for the n-type base layer 2, the p-type base layer 3, the n-type source layer 5, and the floating layer 9. A silicon oxide film and the like, for example, are used for the insulation layer 4 and the gate insulation film 6. A doped polysilicon and the like, for example, are used for the gate electrode 7 and the emitter electrode 8.

Next, operation of the power semiconductor device 1 will be explained. First, a bias, which is positive potential with respect to the emitter electrode 8, is applied to the gate electrode 7. With this operation, an inversion layer is formed on the surface of the gate insulation film 6 of the p-type base layer 3, and electrons are injected into the n-type base layer 2. Accordingly, holes are injected from the collector electrode side into the n-type base layer 2, thereby the power semiconductor device 1 is placed in a turned-on state. Since the collector-gate capacitance Cgc is reduced here, the time necessary for the power semiconductor device 1 to be turned on is shorter than the conventional power semiconductor device described above. The injected holes travel in the n-type base layer 2 and flow into the p-type base layer 3. However, since the holes do not flow into the dummy region, they are accumulated on the emitter electrode 8 side of the n-type base layer 2, thereby injection of the electrons is accelerated, and thus the electron injection promotion effect can be achieved similarly to the conventional power semiconductor device.

As described above, according to the power semiconductor device of the embodiment 1, since the insulation layer is formed in the dummy region as well as the n-type or p-type floating layer is formed on the bottom of the insulation layer, the breakdown voltage can be improved as well as a switching speed can be increased by reducing the collector-gate capacitance Cgc.

### EMBODIMENT 2

The embodiment 1 described above includes the insulation layer and the floating layer formed on the bottom of the insulation layer. However, an embodiment 2 will explain an arrangement for reducing the collector-gate capacitance Cgc while improving the breakdown voltage of a power semiconductor device by forming an electrode in an insulation layer to stabilize an electric field while maintaining the potential of the bottom of insulation layer.

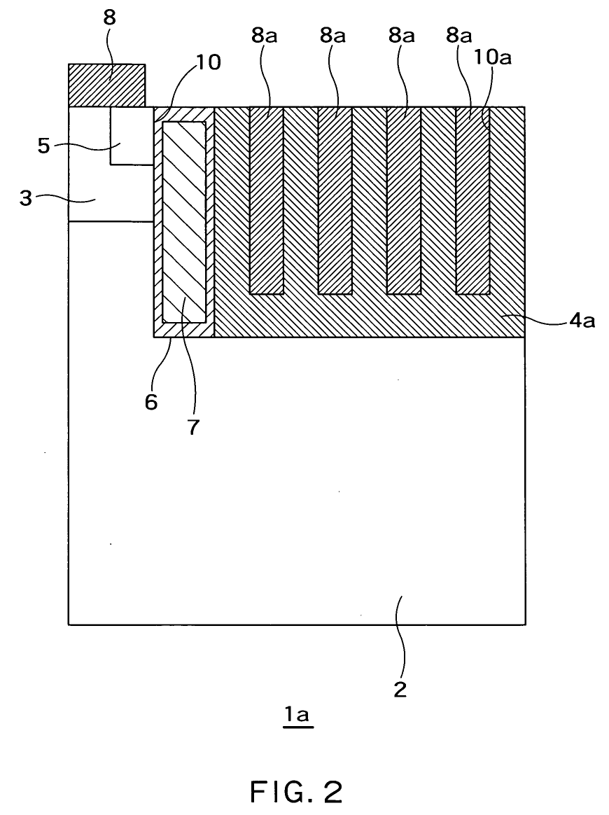

FIG. 2 is a sectional view of a trench MOS gate structure of a power semiconductor device according to the embodiment 2 of the present invention. The power semiconductor device 1a includes an n-type base layer 2, a p-type base layer 3 selectively formed on the n-type base layer 2, and an insulation layer 4a selectively formed in a region in which the p-type base layer 3 on the n-type base layer 2 is not formed. Furthermore, the power semiconductor device 1a includes a trench 10 formed between the p-type base layer 3 and insulation layer 4a so as to separate them from each other and to reach the n-type base layer 2 from the surface of the p-type base layer 3. The power semiconductor device 1a includes a gate insulation film 6 formed on the inner surface of the trench 10 and an n-type source layer 5 selectively formed on the surface of the p-type base layer 3 in contact with the gate insulation film 6. Furthermore, the power semiconductor device 1a includes a gate electrode 7 formed in the trench 10 and insulated from the n-type base layer 2, the p-type base layer 3, and the n-type source layer 5 by the gate insulation film 6, an emitter electrode 8 as a main electrode electrically connected to the n-type source layer 5 and the p-type base layer 3, second trenches 10a formed in the insulation layer 4a so as not to reach the n-type base layer 2 from the surface of the insulation layer 4a, and electrodes 8a formed in the second trenches 10a to maintain the potential of the insulation layer 4a .

Note that, when a vertical trench IGBT is arranged, a collector electrode (not shown) is formed under the n-type base layer 2 through a p-type emitter layer (not shown) as shown in FIG. 1A. Note that, when a lateral trench IGBT is arranged, a collector electrode (not shown) is formed on a p-type emitter layer (not shown) selectively formed on the n-type base layer 2 as shown in FIG. 1B.

Although the electrodes 8a, which are filled in the plural second trenches 10a, are formed in the insulation layer 4a as shown in FIG. 2, the electrodes 8a are electrically connected to the emitter electrode 8 through an element surface and the like so that the potential of the insulation layer 4a can be maintained to the potential of the emitter electrode 8. With this arrangement, the electric field of the bottom of the insulation layer 4a can be stabilized and the breakdown voltage of the power semiconductor device 1a can be improved as well as an electron injection promotion effect can be achieved likewise the embodiment 1.

Furthermore, the thickness of the insulation layer 4a on the bottom of the second trench 10a is made thicker than the thickness of the gate insulation film 6 (in particular, than the thickness of the portion of the gate insulation film 6 facing the channel portion of a MOS structure), thereby an increase of an output capacitance Cec is suppressed.

Furthermore, no collector-gate capacitance is made in the portion of the side surface of the gate insulation film 6 where the insulation layer 4a is formed likewise the embodiment 1, thereby a collector-gate capacitance Cgc is reduced.

Furthermore, the electrodes 8a can be formed deep, convergence of the electric field in the edge portion of the gate electrode 7 on the insulation layer 4a side can be further suppressed, and the collector-gate capacitance Cgc can be further reduced by forming the insulation layer 4a deeper than the trench 10a.

As described above, according to the power semiconductor device of the embodiment 2, since the insulation layer is formed in the dummy region as well as the electrodes, which are connected to the emitter electrode for maintaining the potential of the bottom of the insulation layer, are formed in the insulation layer, the breakdown voltage can be improved as well as a switching speed can be increased by reducing the collector-gate capacitance Cgc.

### EMBODIMENT 3

As described above, although the emitter electrode is formed in the insulation layer to maintain the potential of the bottom of the insulation layer in the embodiment 2, an embodiment 3 will describe an arrangement in which a gate electrode is used in place of the emitter electrode.

Note that, when a vertical trench IGBT is arranged, a collector electrode (not shown) is formed under the n-type base layer 2 through a p-type emitter layer (not shown) as shown in FIG. 1A. Note that, when a lateral trench IGBT is arranged, a collector electrode (not shown) is formed on a p-type emitter layer (not shown) selectively formed on the n-type base layer 2 as shown in FIG. 1B.

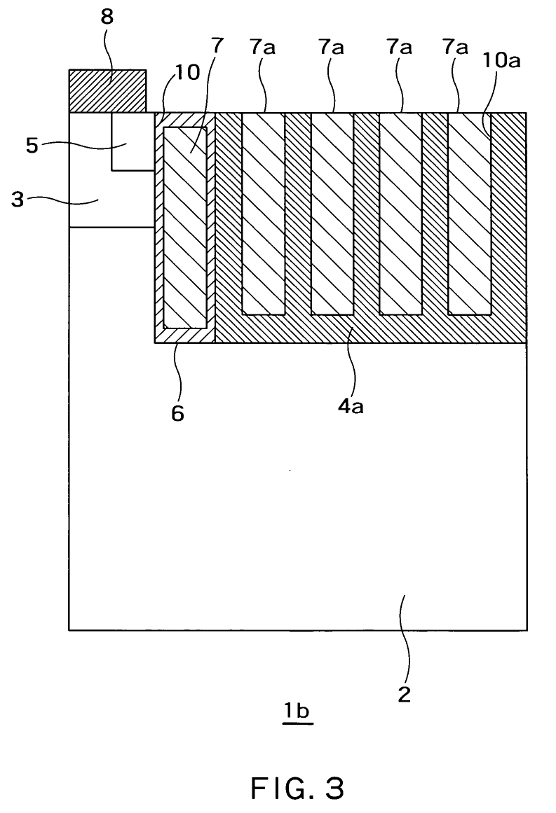

FIG. 3 is a sectional view showing a trench MOS gate structure of a power semiconductor device according to the embodiment 3 of the present invention. The power semiconductor device 1b includes electrodes 7a as electrodes formed in second trenches 10a to maintain the potential of an insulation layer 4a. Note that the other arrangements of the embodiment 3 are the same as those of the embodiment 2 shown in FIG. 2.

As shown in FIG. 3, although the plural electrodes 7a are formed in the insulation layer 4a, a gate electrode 7 is electrically connected to the electrodes 7a through an element surface and the like, thereby the potential of the insulation layer 4a can be maintained to the potential of the gate electrode 7. With this arrangement, the breakdown voltage of the power semiconductor device 1b can be improved likewise the embodiment 2. The wiring resistance of the gate electrode 7 is reduced by connecting it as described above, thereby the controlability of the power semiconductor device 1b can be improved.

The thickness of the insulation layer 4a on the bottom of the second trenches 10a is made thicker than that of the gate insulation film 6, thereby an increase of a collector-gate capacitance Cgc can be suppressed.

Furthermore, the electrodes 7a can be formed deep, convergence of the electric field in the edge portion of the gate electrode 7 on the insulation layer 4a side can be further suppressed, and the collector-gate capacitance Cgc can be further reduced by forming the insulation layer 4a deeper than the trenches 10a.

As described above, according to the power semiconductor device of the embodiment 3, since the gate electrode is formed in the insulation layer to maintain the potential of bottom of the insulation layer, the breakdown voltage and the controlability can be improved as well as a switching speed can be increased by reducing the collector-gate capacitance Cgc.

### EMBODIMENT 4

The insulation layer is formed in the embodiments described up to now to reduce the collector-gate capacitance Cgc. However, an embodiment 4 will describe an arrangement for reducing the collector-gate capacitance Cgc by partly changing the thickness of a gate insulation film.

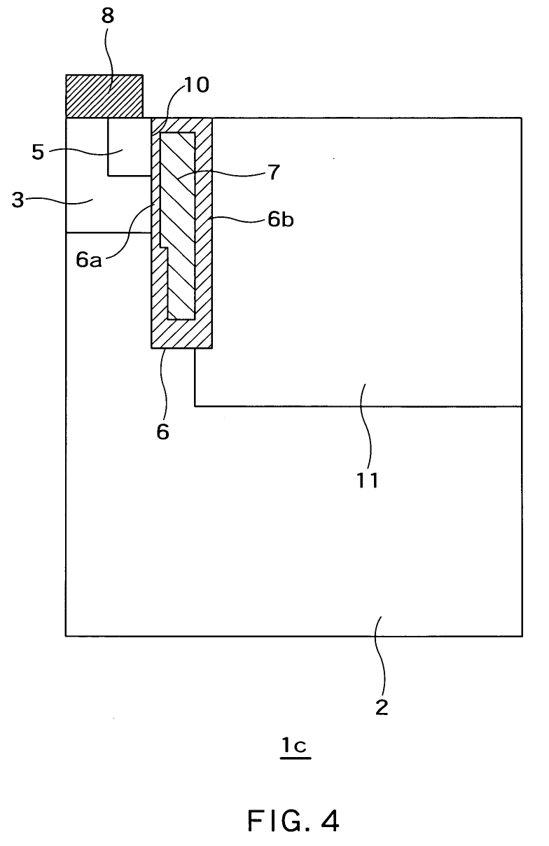

FIG. 4 is a sectional view showing a trench MOS gate structure of a power semiconductor device according to the embodiment 4 of the present invention. The power semiconductor device 1c includes a p-type dummy layer 11 selectively formed in the region in which a p-type base layer 3 on an n-type base layer 2 is not formed, a trench 10 formed between the p-type base layer 3 and the p-type dummy layer 11 to separate them from each other and to reach the n-type base layer 2 from the surface of the p-type base layer 3, and gate insulation films 6a, 6b formed on the inner surface of the trench 10 and having a partly different thickness. Note that the other arrangements of the embodiment 4 are the same as those of the embodiment 1 shown in FIG. 1A, FIG. 1B.

Note that, when a vertical trench IGBT is arranged, a collector electrode (not shown) is formed under the n-type base layer 2 through a p-type emitter layer (not shown) as shown in FIG. 1A. Note that, when a lateral trench IGBT is arranged, a collector electrode (not shown) is formed on a p-type emitter layer (not shown) selectively formed on the n-type base layer 2 as shown in FIG. 1B.

The thickness of the gate insulation film 6b adjacent to the p-type dummy layer 11 and the bottom of the trench 10 is larger than that of the gate insulation film 6a which is adjacent to the p-type base layer 3 (which faces the channel portion of a MOS structure). With this arrangement, since creation of a capacitance is suppressed on the surface of the gate insulation film 6b as compared with a case in which the gate insulation film is uniformly formed as in the conventional art, thereby the collector-gate capacitance Cgc can be reduced. A switching characteristic can be controlled by selecting a desired thickness as the thickness of the gate insulation film 6a. Furthermore, since the p-type dummy layer 11 is formed deeper than the trench 10, a sufficient breakdown voltage can be obtained in the power semiconductor device 1c.

As described above, according to the power semiconductor device of the embodiment 4, since the thickness of the gate insulation film is increased on the p-type dummy layer side and on the bottom of the trench as well as the p-type dummy layer is made deeper than the trench, the breakdown voltage can be improved as well as a switching speed can be increased by reducing the collector-gate capacitance Cgc.

### EMBODIMENT 5

As described above, although the gate electrode is formed in the insulation layer of the embodiment 3 to maintain the potential of the bottom of the insulation layer, an embodiment 5 will describe another arrangement of a gate electrode for improvement of the controlability of a power semiconductor device.

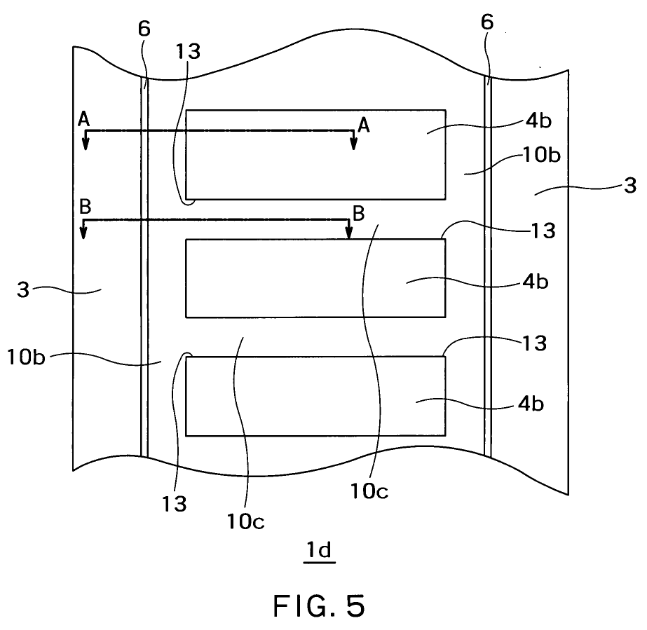

FIG. 5 is a plan view for explaining a main portion of a trench MOS gate structure of a power semiconductor device according to an embodiment 5 of the present invention. Note that an n-type source layer, an emitter electrode, and a gate electrode are omitted in FIG. 5 for the convenience of explanation.

As shown in the FIG. 5, a second trench 10c communicates with a first trench 10b, and a gate electrode in the first trench 10b is electrically connected to a gate electrode in the second trench 10c in the communicating portion 13 thereof. Note that these gate electrodes may be further electrically connected to each other on an element surface and the like. In a dummy region of the power semiconductor device 1d, after a p-type base layer is formed on an n-type base layer, the first trench 10b and the second trench 10c are disposed in a ladder shape and formed at the same time by being etched, and a gate insulation film 6 is formed by being subjected to thermal oxidation. The portion of the gate insulation film 6 facing the channel portion of a MOS structure is partly etched and adjusted to a desired thickness. Thereafter, the gate electrodes are formed by filling the trenches 10b, 10c with a gate electrode material.

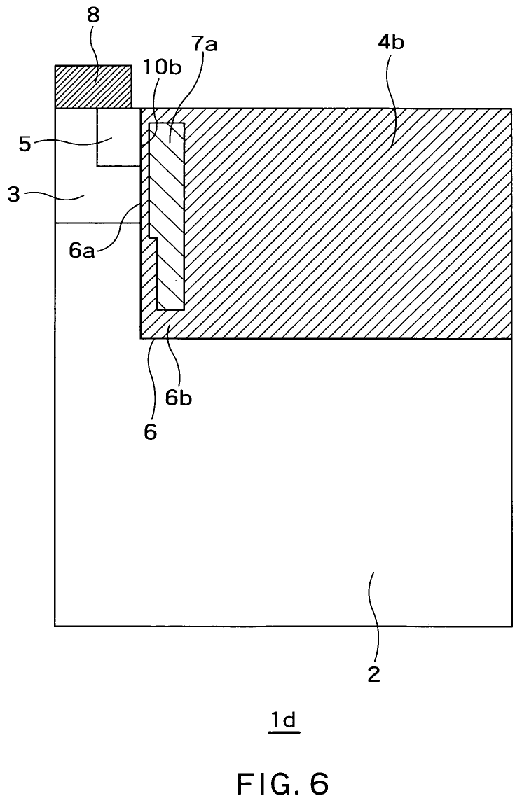

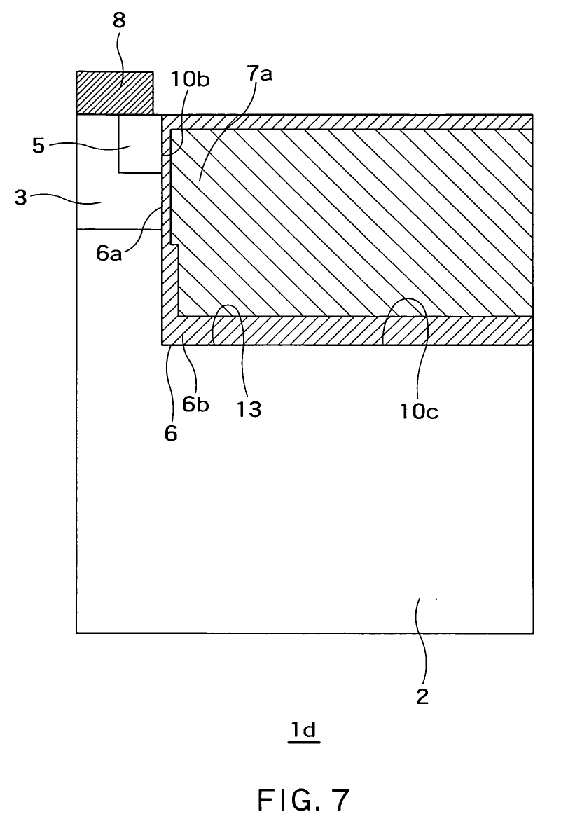

The power semiconductor device made as described above will be described using FIGS. 6 and 7.

FIG. 6 is a sectional view showing a cross section of the power semiconductor device 1d taken along the line A-A of FIG. 5. As shown in the FIG. 6, since the second trench 10c is not formed in the A-A cross section, a gate insulation film 6b on an insulation layer 4b side of the first trench 10b is connected to and integrated with an insulation layer 4b. The thickness of the gate insulation film 6b on the bottom of the first trench 10b is made larger than that of the gate insulation film 6a on the p-type base layer side of the first trench 10b (that is, larger than the portion facing the channel portion of the of a MOS structure). Since the gate insulation film 6b on the insulation layer 4b side is connected to and integrated with the insulation layer 4b as described above, the thickness of the insulation film including the insulation layer 4b is larger than that of the gate insulation film 6a on the p-type base layer side. Note that the other arrangements of the embodiment 5 are the same as those of the embodiment 3.

Note that, when a vertical trench IGBT is arranged, a collector electrode (not shown) is formed under the n-type base layer 2 through a p-type emitter layer (not shown) as shown in FIG. 1A. Note that, when a lateral trench IGBT is arranged, a collector electrode (not shown) is formed on a p-type emitter layer (not shown) selectively formed on the n-type base layer 2 as shown in FIG. 1B.

FIG. 7 is a sectional view showing a cross section of the power semiconductor device 1d taken along the line B-B of FIG. 5. As shown in the FIG. 7, the second trench 10c communicates with first trench 10b, and a gate electrode 7a in the first trench 10b is electrically connected to a gate electrode 7a in the second trench 10c in the communicating portion 13. Furthermore, although the gate insulation film 6a on the p-type base layer side and the gate insulation film 6b on the bottom side of the first trench 10b are the same as those of FIG. 6, the thickness of the insulation layer 4b on the bottom of the second trench 10c is larger than that of the gate insulation film 6a so as to suppress an increase of a collector-gate capacitance Cgc. Furthermore, the collector-gate capacitance Cgc can be reduced by forming the insulation layer 4b deeper than the first trench 10b.

As shown in FIGS. 5 to 7, since the electrodes 7a are formed in the insulation layer 4b in a ladder shape, the potential of the insulation layer 4b can be maintained to the potential of the gate electrodes 7a. With this arrangement, the breakdown voltage of the power semiconductor device 1d can be improved likewise the embodiment 3. Furthermore, the wiring resistance of the gate electrode 7a is reduced by the arrangement, thereby the controlability of the power semiconductor device 1d can be improved.

Furthermore, in general, it is difficult to form a wide trench to an insulation layer and to form a gate electrode to the trench uniformly in order to obtain a uniform potential in the insulation layer. However, it is sufficiently possible to form the first and second ladder-shaped trenches 10b, 10c and to form the gate electrodes 7a by burying the gate electrode material in the trenches. Accordingly, the ladder-shaped gate electrode structure that can provide the insulation layer 4b with the uniform potential can be realized.

As described above, according to the power semiconductor device of the embodiment 5, since the electrodes connected to the gate electrodes are formed in the gate insulation film and the insulation layer of the dummy region in the ladder shape as well as the thicknesses of the bottoms of the gate insulation film and the insulation layer are increased, the breakdown voltage and the controlability of the power semiconductor device can be improved as well as the switching speed there of can be increased by reducing the collector-gate capacitance Cgc.

### EMBODIMENT 6

Although the ladder-shaped gate electrodes are formed in the insulation layer in the embodiment 5, an embodiment 6 will describe another arrangement of gate electrodes for improving the controlability of a power semiconductor device.

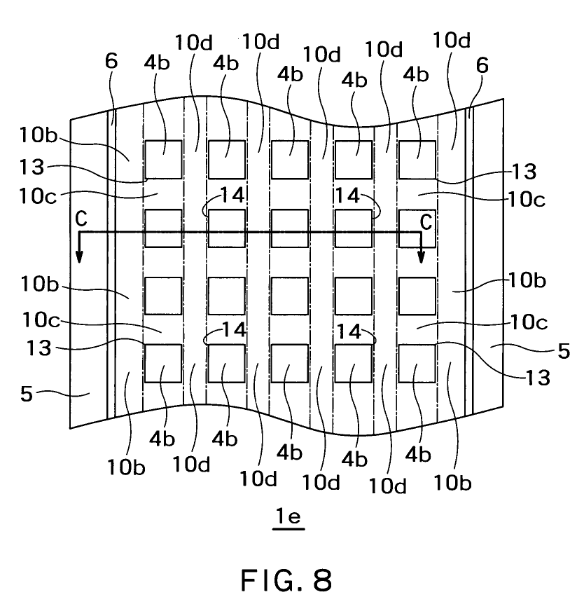

FIG. 8 is a plan view explaining an arrangement of a main portion of a power semiconductor device according to the embodiment 6 of the present invention. Note that an n-type source layer, an emitter electrode, and a gate electrode are omitted in FIG. 8 for the convenience of explanation.

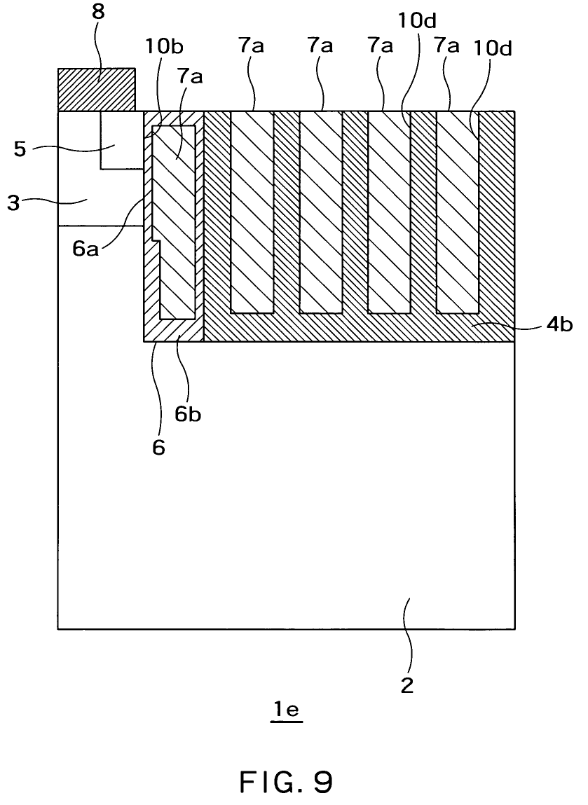

The embodiment 6 is the same as the embodiment 5 except that a dummy region of a power semiconductor device 1e communicates with a second trench 10c as well as a third trench 10d is further formed in parallel with the first trench 10b as shown in the FIG. 8. As described above, the third trench 10d communicates with the second trench 10c, and a gate electrode in the second trench 10c is electrically connected to a gate electrode in the third trench 10d in the communicating portions 14 thereof. Note that, for the convenience of explanation, the third trench 10d including the portion thereof communicating with the second trench 10c is shown by virtual dashed lines. The cross section of the power semiconductor device 1e along the line C-C of FIG. 8 is as shown in a sectional view of FIG. 9, and an insulation layer 4b has the same structure as the insulation layer 4a of FIG. 3.

Note that these gate electrodes may be further electrically connected to each other on an element surface and the like.

Note that, when a vertical trench IGBT is arranged, a collector electrode (not shown) is formed under the n-type base layer 2 through a p-type emitter layer (not shown) as shown in FIG. 1A. Note that, when a lateral trench IGBT is arranged, a collector electrode (not shown) is formed on a p-type emitter layer (not shown) selectively formed on the n-type base layer 2 as shown in FIG. 1B.

As described above, according to the power semiconductor device of the embodiment 6, since the gate electrodes are formed in the gate insulation film and the insulation layer of the dummy region in a lattice shape, the controlability of the power semiconductor device can be improved by further reducing the wiring resistance of the gate electrodes.

### EMBODIMENT 7

As described above, in the embodiment 2, the emitter electrode is formed in the insulation layer. However, an embodiment 7 will particularly describe an arrangement for reducing a collector-gate capacitance Cgc by forming an emitter electrode on the inner surface of a trench formed in an insulation layer.

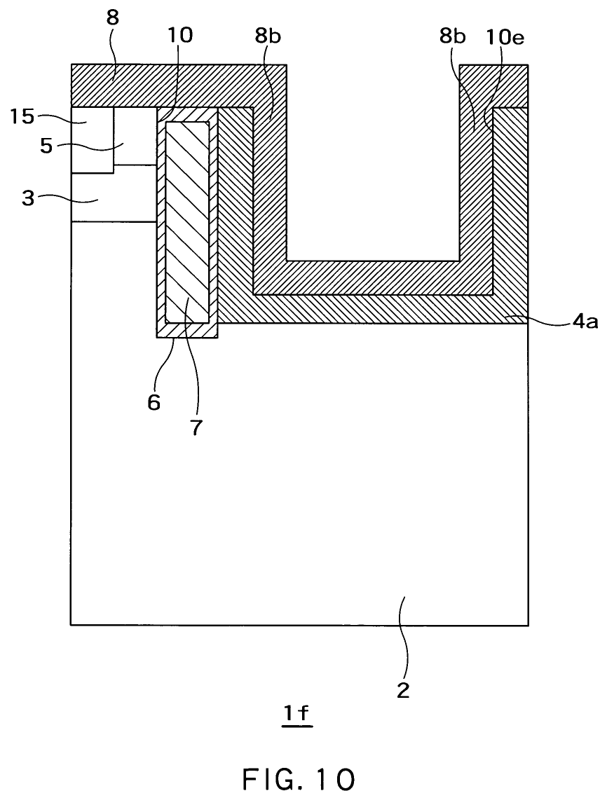

FIG. 10 is a sectional view showing a trench MOS gate structure of a power semiconductor device according to the embodiment 7 of the present invention.

As shown in FIG. 10, the power semiconductor device If includes an electrode 8b formed on the inner surface of a second trench 10e as an electrode for setting the dummy region of side of a gate electrode 7 to the source potential through the gate insulation film 6 and an insulation layer 4a in which the second trench 10e is formed. Note that the embodiment 7 is the same as the embodiment 2 shown in FIG. 2 except that a p-type contact layer 15 is formed on a p-type base layer 3.

As shown in the FIG. 10, since the electrode 8b is electrically connected to an emitter electrode 8 through an element surface and the like. The source potential of an electrode 8b is set to the dummy region of side of a gate electrode 7 through the gate insulation film 6 and the insulation layer 4a. Accordingly, since no depletion layer enters the dummy region, the potential of the dummy region is not varied when the gate electrode 7 is turned on and off. With this arrangement, the dV/dt variation of the gate potential caused by the variation of the potential of the dummy region can be suppressed.

With this arrangement, an electron injection promotion effect similar to that of the embodiment 2 can be achieved as well as the dv/dt variation of the gate potential of the power semiconductor device if can be suppressed. Note that malfunction of other elements can be suppressed by suppressing the dv/dt variation of the gate potential.

Furthermore, no collector-gate capacitance is made in the portion of the side surface of the gate insulation film 6 where the insulation layer 4a is formed likewise the embodiment 2, thereby a collector-gate capacitance Cgc is reduced.

Note that, when a vertical trench IGBT is arranged, a collector electrode (not shown) is formed under the n-type base layer 2 through a p-type emitter layer (not shown) as shown in FIG. 1A. Note that, when a lateral trench IGBT is arranged, a collector electrode (not shown) is formed on a p-type emitter layer (not shown) selectively formed on the n-type base layer 2 as shown in FIG. 1B.

As described above, according to the power semiconductor device of the embodiment 7, since the insulation layer is formed in the dummy region and the electrode, which is electrically connected to the emitter electrode, is formed in the insulation layer, the dv/dt variation of the gate potential is suppressed as well as the switching speed of the power semiconductor device can be increased by reducing the collector-gate capacitance Cgc.

### EMBODIMENT 8

As described above, in the embodiment 7, the emitter electrode is formed on the inner surface of the trench formed in the insulation layer. However, an embodiment 8 will describe an arrangement for improving a breakdown voltage by further forming a floating layer to the bottom of an insulation layer.

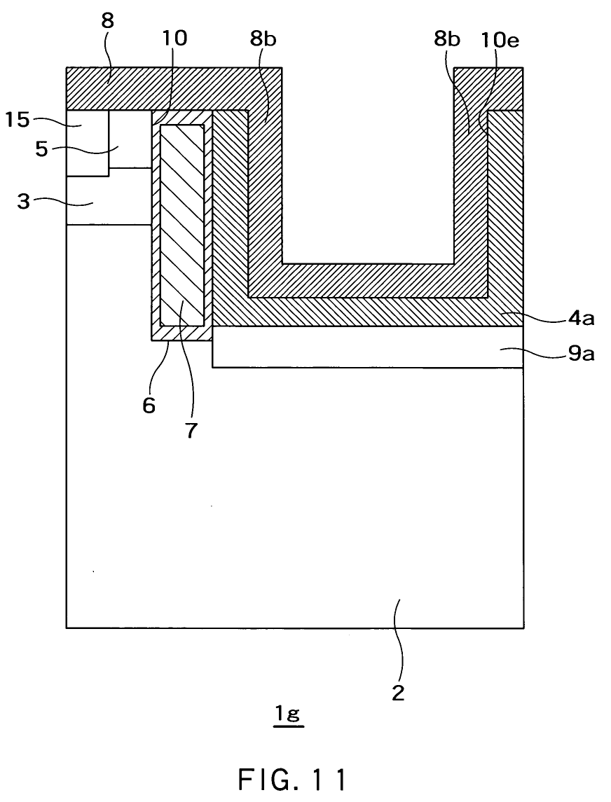

FIG. 11 is a sectional view showing a trench MOS gate structure of a power semiconductor device according to the embodiment 8 of the present invention.

As shown in FIG. 11, the power semiconductor device 1g further includes a floating layer 9a acting as a p-type diffusion layer with a concentration higher than a p-type base layer 3 and formed on the bottom of an insulation layer 4a so as to cover it. With this arrangement, the breakdown voltage of the power semiconductor device 1g can be improved. Note that the other arrangements of the embodiment 8 are the same as those of the embodiment 7 shown in FIG. 10.

Note that, when a vertical trench IGBT is arranged, a collector electrode (not shown) is formed under the n-type base layer 2 through a p-type emitter layer (not shown) as shown in FIG. 1A. Note that, when a lateral trench IGBT is arranged, a collector electrode (not shown) is formed on a p-type emitter layer (not shown) selectively formed on the n-type base layer 2 as shown in FIG. 1B.

As described above, according to the power semiconductor device of the embodiment 8, since the p-type floating layer with the concentration higher than the p-type base layer 3 is formed on the bottom of the insulation layer 4a so as to cover it, the breakdown voltage can be further improved in addition to the effect of the embodiment 7.

### EMBODIMENT 9

As described above, in the embodiment 8, the emitter electrode is formed on the inner surface of the trench formed in the insulation layer and further the floating layer is formed on the bottom of the insulation layer. However, an embodiment 9 will describe an arrangement for reducing a region contributing to a dv/dt variation by separating a gate electrode by an insulation film.

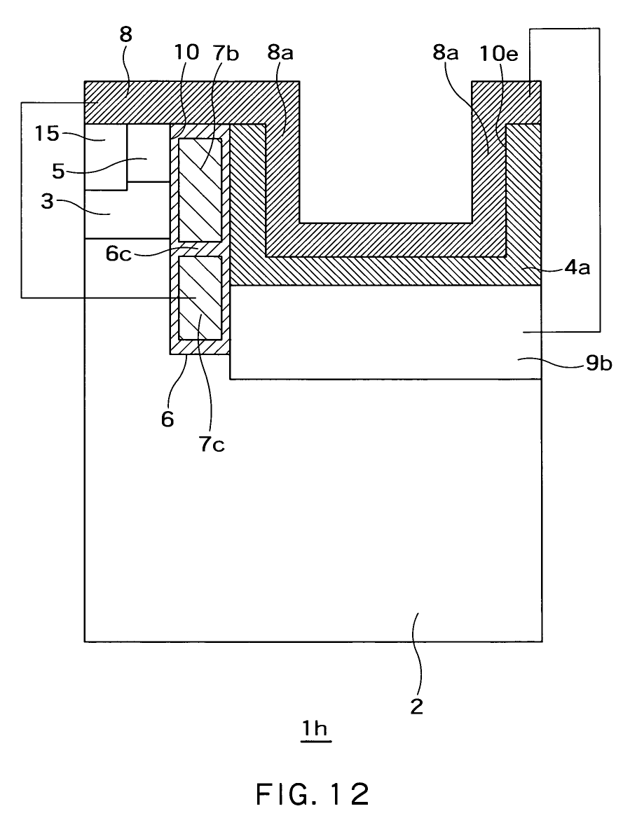

FIG. 12 is a sectional view showing a trench MOS gate structure of a power semiconductor device according to the embodiment 9 of the present invention.

As shown in FIG. 12, the power semiconductor device 1h includes, as a gate electrode, a first gate electrode 7b in contact with a p-type base layer 3 and an n-type source layer 5 acting as a channel portion through a gate insulation films 6, and a second gate electrode 7c formed below the first gate electrode 7b as well as separated therefrom by a separation insulation film 6c. Furthermore, a floating layer 9b acting as a p-type diffusion layer is formed on the bottom of an insulation layer 4a so as to cover it.

The first gate electrode 7b is in contact with an electrode 8b through the gate insulation films 6 and the insulation layer 4a. Furthermore, the upper surface of the p-type floating layer 9b, which is the Si surface of a dummy region, is located below the lower surface of the first gate electrode 7b.

In contrast, the second gate electrode 7c is in contact with an n-type base layer 2 through the gate insulation film 6 and is not in contact with a channel portion. An emitter electrode 8 is electrically connected to the second gate electrode 7c at, for example, the terminal end of the element region of the power semiconductor device lh. With this arrangement, the dv/dt variation of a gate potential is suppressed.

Furthermore, the floating layer 9b is electrically connected to the emitter electrode 8 at the terminal end of the element region of the power semiconductor device 1h.

Note that the other arrangements of the embodiment 9 are the same as those of the embodiment 8 shown in FIG. 11.

With this arrangement, the region of the gate electrode that contributes to the dv/dt variation of the gate potential is reduced, thereby the depth of a second trench 10e of the insulation layer 4a can be reduced. Accordingly, the power semiconductor device 1h can be made more easily than that of the embodiment 8. Furthermore, since the dummy region is fixed to the emitter potential, a collector-gate capacitance Cgc can be reduced and a breakdown voltage can be improved.

Note that, when a vertical trench IGBT is arranged, a collector electrode (not shown) is formed under the n-type base layer 2 through a p-type emitter layer (not shown) as shown in FIG. 1A. Note that, when a lateral trench IGBT is arranged, a collector electrode (not shown) is formed on a p-type emitter layer (not shown) selectively formed on the n-type base layer 2 as shown in FIG. 1B.

As described above, the power semiconductor device of the embodiment 9 can be made more easily than that of the embodiment 8 while suppressing the dv/dt variation of the gate potential and improving the breakdown voltage.

### EMBODIMENT 10

As described above, in the embodiment 9, the arrangement for electrically connecting the second gate electrode to the emitter electrode is described. However, an embodiment 10 describes an arrangement in which a second gate electrode is electrically connected to a first gate electrode through a resistor.

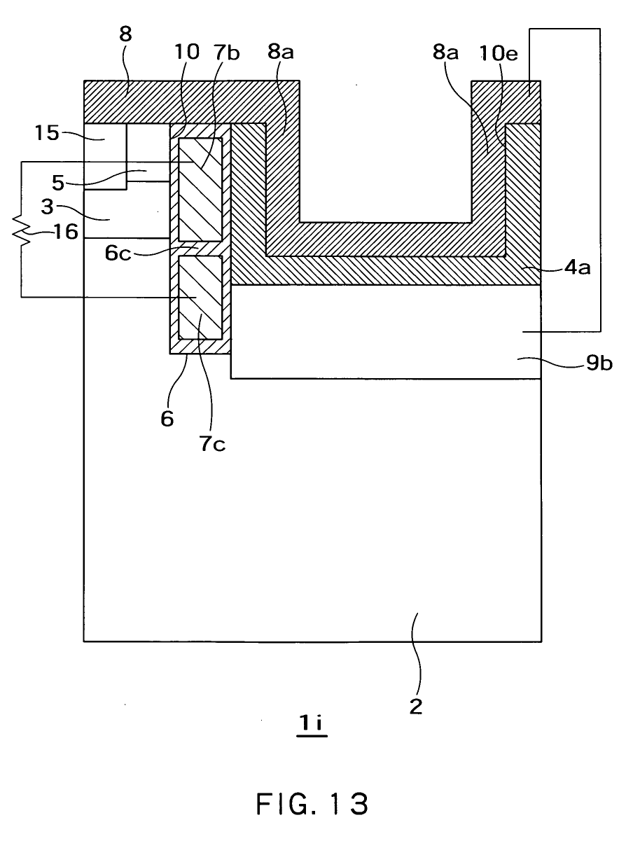

FIG. 13 is a sectional view showing a trench MOS gate structure of a power semiconductor device according to the embodiment 10 of the present invention.

As shown in FIG. 13, in the power semiconductor device 1i, a first gate electrode 7b is electrically connected to a second gate electrode 7c at the terminal end of the element region of the power semiconductor device 1i through a high resistor 16. Note that the other arrangements of the embodiment 10 are the same as those of the embodiment 9 shown in FIG. 12.

The resistor 16 has a high resistance value of several tens of ohms. With this arrangement, since the potential of the second gate electrode 7c is varied after the variation of the potential of the first gate electrode 7b, the abrupt dv/dt variation of a gate potential can be suppressed.

With this arrangement, the region of the gate electrode that contributes to the dv/dt variation of the gate potential is reduced, thereby the depth of a second trench 10e of an insulation layer 4a can be reduced. Accordingly, the power semiconductor device 1i can be made more easily than that of the embodiment 8.

Note that, when a vertical trench IGBT is arranged, a collector electrode (not shown) is formed under the n-type base layer 2 through a p-type emitter layer (not shown) as shown in FIG. 1A. Note that, when a lateral trench IGBT is arranged, a collector electrode (not shown) is formed on a p-type emitter layer (not shown) selectively formed on the n-type base layer 2 as shown in FIG. 1B.

As described above, the power semiconductor device of the embodiment 10 can be made more easily than that of the embodiment 8 while suppressing the abrupt dv/dt variation of the gate potential and improving a breakdown voltage.

### EMBODIMENT 11

As described above, in the embodiment 9, the electrode is formed on the inner surface of the trench formed in the insulation layer. However, an embodiment 11 will describe an arrangement in which an electrode electrically connected to an emitter electrode is formed on the upper surface of an insulation layer without forming a trench to the insulation layer different from the embodiment 1.

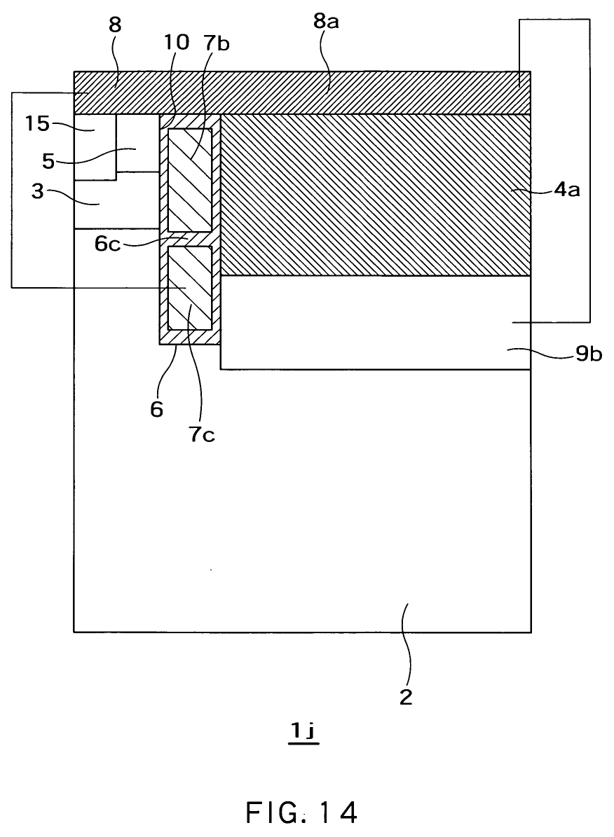

FIG. 14 is a sectional view showing a trench MOS gate structure of a power semiconductor device according to the embodiment 11 of the present invention.

As shown in FIG. 14, in the power semiconductor device 1j, no trench is formed in an insulation layer 4a and an electrode 8a electrically connected to an emitter electrode 8 is formed on the upper surface of the insulation layer 4a. Furthermore, the floating layer 9b is electrically connected to the emitter electrode 8 at the terminal end of the element region of the power semiconductor device 1j. Note that the other arrangements of the embodiment 11 are the same as those of the embodiment 9 shown in FIG. 12.

With this arrangement, since a dummy region is fixed to an emitter potential likewise the embodiment 9, a collector-gate capacitance Cgc can be reduced and a breakdown voltage can be improved.

Note that, when a vertical trench IGBT is arranged, a collector electrode (not shown) is formed under the n-type base layer 2 through a p-type emitter layer (not shown) as shown in FIG. 1A. Note that, when a lateral trench IGBT is arranged, a collector electrode (not shown) is formed on a p-type emitter layer (not shown) selectively formed on the n-type base layer 2 as shown in FIG. 1B.

As described above, according to the power semiconductor device of the embodiment 11, the dv/dt variation of a gate potential can be suppressed as well as a collector-gate capacitance Cgc can be reduced and a breakdown voltage can be improved.

### EMBODIMENT 12

As described above, in the embodiment 10, the electrode is formed on the inner surface of the trench formed in the insulation layer. However, an embodiment 12 will describe an arrangement in which an electrode electrically connected to an emitter electrode is formed on the upper surface of an insulation layer without forming a trench to the insulation layer different from the embodiment 1.

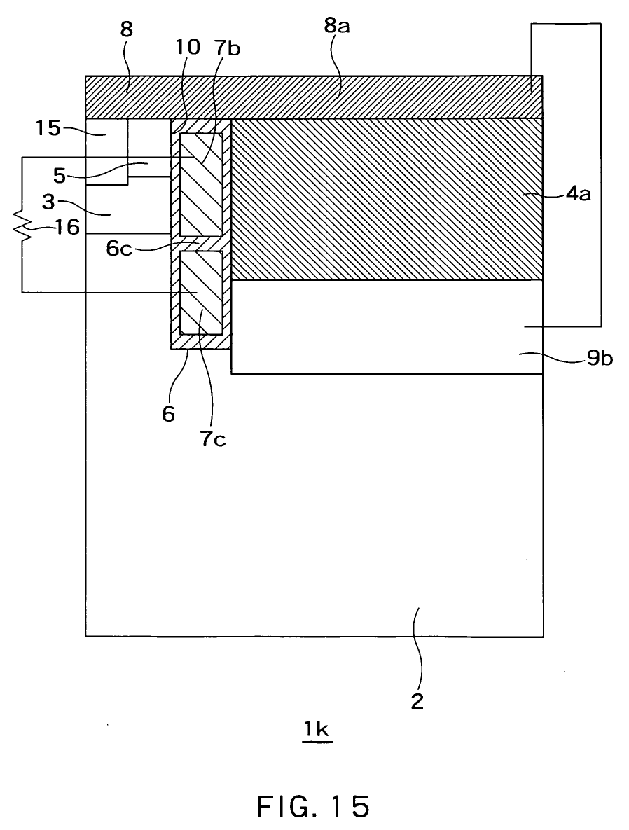

FIG. 15 is a sectional view showing a trench MOS gate structure of a power semiconductor device according to the embodiment 12 of the present invention.

As shown in FIG. 15, in the power semiconductor device 1k, no trench is formed in the insulation layer 4a and the electrode 8a electrically connected to the emitter electrode 8 is formed on the upper surface of the insulation layer 4a. Furthermore, the floating layer 9b is electrically connected to the emitter electrode 8 at the terminal end of the element region of the power semiconductor device 1k. Note that the other arrangements of the embodiment 12 are the same as those of the embodiment 10 shown in FIG. 13.

With this arrangement, since a dummy region is fixed to an emitter potential likewise the embodiment 10, a collector-gate capacitance Cgc can be reduced and a breakdown voltage can be improved.

Note that, when a vertical trench IGBT is arranged, a collector electrode (not shown) is formed under the n-type base layer 2 through a p-type emitter layer (not shown) as shown in FIG. 1A. Note that, when a lateral trench IGBT is arranged, a collector electrode (not shown) is formed on a p-type emitter layer (not shown) selectively formed on the n-type base layer 2 as shown in FIG. 1B.

As described above, according to the power semiconductor device of the embodiment 12, the dv/dt variation of a gate potential can be suppressed as well as the collector-gate capacitance Cgc can be reduced and the breakdown voltage can be improved.

What is claimed is:

1. A power semiconductor device comprising:
a first conductive type base layer;
a second conductive type base layer selectively formed on the first conductive type base layer;
an insulation layer formed in the region on the first conductive type base layer on which the second conductive type base layer is not formed;
a gate insulation film formed on the inner surface of a trench formed between the second conductive type base layer and the insulation layer so as to separate them from each other and to reach the first conductive type base layer from the surface of the second conductive type base layer;
a first conductive type source layer selectively formed on the surface of the second conductive type base layer in contact with the gate insulation film;
a gate electrode formed in the trench and insulated from the first conductive type base layer, the second conductive type base layer, and the first conductive type source layer by the gate insulation film;
a main electrode electrically connected to the first conductive type source layer and the second conductive type base layer; and
a first conductive type or second conductive type floating layer formed on the bottom of the insulation layer.

2. The power semiconductor device according to claim 1, wherein the depth of the insulation layer is deeper than the depth of the trench.

3. The power semiconductor device according to claim 1, wherein:
the floating layer is a second conductive type floating layer;
the gate electrode comprises a first gate electrode in contact with the second conductive type base layer and the first conductive type source layer acting as a channel portion through the gate insulation film and a second gate electrode formed under the first gate electrode as well as separated from the first gate electrode by a separation insulation film;
the first gate electrode is in contact with the electrode through at least the gate insulation film, and the upper surface of the second conductive type floating layer is located below the lower surface of the first gate electrode; and
the second gate electrode is electrically connected to the main electrode, and the second conductive type floating layer is electrically connected to the main electrode.

4. The power semiconductor device according to claim 1, wherein:
the floating layer is a second conductive type floating layer;
the gate electrode comprises a first gate electrode, which is in contact with the second conductive type base layer and the first conductive type source layer acting as a channel portion through the gate insulation film, and a second gate electrode which is formed under the first gate electrode as well as separated from the first gate electrode by a separation insulation film;
the first gate electrode is in contact with the electrode through at least the gate insulation film, and the upper surface of the second conductive type floating layer is located below the lower surface of the first gate electrode;
the second gate electrode is electrically connected to a first gate electrode through a resistor; and
the second conductive type floating layer is electrically connected to the main electrode.

5. A power semiconductor device comprising:
a first conductive type base layer;
a second conductive type base layer selectively formed on the first conductive type base layer;
an insulation layer formed in the region on the first conductive type base layer on which the second conductive type base layer is not formed;
a gate insulation film formed on the inner surface of a first trench formed between the second conductive type base layer and the insulation layer to separate them from each other and to reach the first conductive type base layer from the surface of the second conductive type base layer;
a first conductive type source layer selectively formed on the surface of the second conductive type base layer in contact with the first gate insulation film;
a gate electrode formed in the first trench and insulated from the first conductive type base layer, the second conductive type base layer, and the first conductive type source layer by the gate insulation film;
a main electrode electrically connected to the first conductive type source layer and the second conductive type base layer; and
an electrode formed in a second trench to maintain the potential of the insulation layer, wherein the second trench is formed in the insulation layer so as not to reach the first conductive type base layer from the surface of the insulation layer.

6. The power semiconductor device according to claim 5, wherein the electrode is electrically connected to the main electrode.

7. The power semiconductor device according to claim 5, wherein the electrode is electrically connected to the gate electrode.

8. The power semiconductor device according to claim 5, wherein the thickness of the insulation layer on the bottom of the second trench is larger than that of the gate insulation film.

9. The power semiconductor device according to claim 5, wherein the gate electrode in the first trench is electrically connected to the electrode in the second trench in the communicating potion of the first trench and second trench.

10. The power semiconductor device according to claim 5, wherein the thickness of the gate insulation layer on the bottom of the first trench is larger than that of the gate insulation film on the second conductive type base layer side.

11. The power semiconductor device according to claim 5, wherein the thickness of the insulation layer on the bottom of the second trench is larger than that of the gate insulation film facing the channel portion of the second conductive type base layer.

12. The power semiconductor device according to claim 6, wherein a second conductive type floating layer is formed on the bottom of the insulation layer.

13. The power semiconductor device according to claim 12, wherein the concentration of the second conductive type floating layer is higher than that of the first conductive type base layer.

14. The power semiconductor device according to claim 12, wherein:
the gate electrode comprises a first gate electrode, which is in contact with the second conductive type base layer and the first conductive type source layer acting as a channel portion through the gate insulation film, and a second gate electrode which is formed under the first gate electrode as well as separated from the first gate electrode by a separation insulation film;
the first gate electrode is in contact with the electrode through at least the gate insulation film, and the upper surface of the second conductive type floating layer is located below the lower surface of the first gate electrode; and
the second gate electrode is electrically connected to the main electrode, and the second conductive type floating layer is electrically connected to the main electrode.

15. The power semiconductor device according to claim 12, wherein the gate electrode comprises a first gate electrode in contact with the second conductive type base layer and the first conductive type source layer acting as a channel portion through the gate insulation film and a second gate electrode formed under the first gate electrode as well as separated from the first gate electrode by a separation insulation film;
the first gate electrode is in contact with the electrode through at least the gate insulation film and the upper surface of the second conductive type floating layer is located below the lower surface of the first gate electrode;
the second gate electrode is electrically connected to the first gate electrode through a resistor; and
the second conductive type floating layer is electrically connected to the main electrode.

16. A power semiconductor device comprising:
a first conductive type base layer;
a second conductive type base layer selectively formed on the first conductive type base layer;
a second conductive type dummy layer selectively formed in the region on the first conductive type base layer on which the second conductive type base layer is not formed;
a gate insulation film formed on the inner surface of a trench formed between the second conductive type base layer and the second conductive type dummy layer so as to separate them from each other and to reach the first conductive type base layer from the surface of the second conductive type base layer;
a first conductive type source layer selectively formed on the surface of the second conductive type base layer in contact with the gate insulation film;
a gate electrode formed in the trench and insulated from the first conductive type base layer, the second conductive type base layer, and the first conductive type source layer by the gate insulation film; and
a main electrode electrically connected to the first conductive type source layer and the second conductive type base layer,
wherein the thickness of the gate insulation film on the side wall portion of the trench on the second conductive type dummy layer side and on the bottom of the trench is larger than the thickness of the gate insulation film facing the channel portion of the second conductive type base layer.

17. The power semiconductor device according to claim 16, wherein the depth of the second conductive type dummy layer is deeper than the depth of the trench.

18. The power semiconductor device according to claim 1, further comprising:
a second conductive type emitter layer selectively formed in the first conductive type base layer;
a second main electrode formed on the second conductive type emitter layer.

19. The power semiconductor device according to claim 5, further comprising:
a second conductive type emitter layer selectively formed in the first conductive type base layer;
a second main electrode formed on the second conductive type emitter layer.

20. The power semiconductor device according to claim 16, further comprising:
a second conductive type emitter layer selectively formed in the first conductive type base layer;
a second main electrode formed on the second conductive type emitter layer.
